(19) United States
(12) Patent Application Publication
(10) Pub. No.: US 2010/0200831 A1
(43) Pub. Date: Aug. 12, 2010

(54) Non-volatile memory devices and methods of fabricating the same

(75) Inventors: Sang-Hun Jeon, Yongin-si (KR); Moon-Sook Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/656,634

(22) Filed: Feb. 5, 2010

(30) Foreign Application Priority Data
Feb. 6, 2009 (KR) 10-2009-0009803

(51) Int. Cl. H01L 45/00

(52) U.S. Cl. 257/4; 257/E45.001

(57) ABSTRACT

Non-volatile memory devices including a lower electrode formed on a substrate; an active memory material formed on the lower electrode; an upper electrode formed on the active memory material; and an adhesive layer formed in part of a region between the active memory material and the upper electrode.

### CROSS-REFERENCE TO RELATED APPLICATIONS

This application claims priority under 35 U.S.C. §119 to Korean Patent Application No. 10-2009-0009803 filed on Feb. 6, 2009 in the Korean Intellectual Property Office (KIPO), the entire contents of which is incorporated herein by reference.

### BACKGROUND

1. Field

Example embodiments of the inventive concepts relate to non-volatile memory devices and methods of fabricating the same, and more particularly, to non-volatile memory devices with enhanced reliability and methods of fabricating the same.

2. Description of the Related Art

Non-volatile memory devices are memory elements that may not lose data stored therein even when power to the memory element is turned off. Recently, with the increase in the use of portable electronic devices (e.g., mobile terminals, various smart cards, electronic bills, digital cameras, personal mobile terminals, digital audio players, and multimedia players), there has been a surge in the demand for non-volatile memory elements. In addition, as technical limitations of conventional silicon memory elements are revealed, high-speed, high-capacity, low power-consuming, and inexpensive next-generation non-volatile memory elements, which can overcome physical limitations of the conventional silicon memory elements, are actively being developed.

These next-generation non-volatile memory elements may include resistive random access memories (RRAMs), ferroelectric random access memories (FRAMs), phase-change random access memories (PRAM), and magnetic random access memories (MRAMs), which may be classified according to the material of a memory cell.

### SUMMARY

Aspects of the inventive concepts may provide non-volatile memory devices with enhanced reliability and methods of fabricating non-volatile memory devices with enhanced reliability. Example embodiments of the inventive concepts are not restricted to the example embodiments set forth herein. The above and other aspects of example embodiments of the inventive concepts will become more apparent to one of ordinary skill in the art to which the inventive concepts pertain by referencing the detailed description given below.

According to example embodiments of the inventive concepts, a non-volatile memory device includes an active memory layer, an electrode on the active memory layer, and an adhesive layer between part of the active memory layer and part of the electrode.

According to example embodiments of the inventive concepts, a non-volatile memory device includes a lower electrode formed on a substrate; an active memory material formed on the lower electrode; an upper electrode formed on the active memory material; and an adhesive layer formed in part of a region between the active memory material and the upper electrode.

According to example embodiments of the inventive concepts, methods of fabricating a non-volatile memory device include depositing an active memory material and a first electrode, printing an adhesive layer on a part of the active memory material, and printing a second electrode on a part of the active memory material where the adhesive layer is not formed.

According to example embodiments of the inventive concepts, methods of fabricating a non-volatile memory device include depositing a lower electrode and an active memory material; printing an adhesive layer on part of the active memory material; and printing an upper electrode on the remaining regions of the active memory material where the adhesive layer is not formed.

### BRIEF DESCRIPTION OF THE DRAWINGS

Example embodiments of the inventive concepts will be more clearly understood from the following brief description taken in conjunction with the accompanying drawings. FIGS. 1-11 represent non-limiting, example embodiments as described herein.

FIG. 1A is a plan view of a non-volatile memory device according to example embodiments of the inventive concepts;

FIG. 1B is a cross-sectional view of the non-volatile memory device of FIG. 1A taken along the line IB-IB′;

FIG. 1C is a plan view of the adhesive layer of the non-volatile memory device illustrated in FIGS. 1A and 1B;

FIG. 2A is a graph of polarization as a function of gate voltage (Vg) illustrating variation in characteristics of the non-volatile memory device illustrated in FIGS. 1A and 1B when the non-volatile memory device is a ferroelectric random access memory (FRAM);

FIG. 2B is a graph of gate current (Ig) as a function of gate voltage (Vg) illustrating variation in characteristics of the non-volatile memory device illustrated in FIGS. 1A and 1B when the non-volatile memory device is a resistive random access memory (RRAM);

FIGS. 3A-5B are diagrams illustrating non-volatile memory devices according to example embodiments of the inventive concepts;

FIGS. 6-9 are diagrams illustrating methods of fabricating non-volatile memory devices according to example embodiments of the inventive concepts;

FIG. 10 is a schematic diagram roughly illustrating a memory card according to example embodiments; and

FIG. 11 is a block diagram roughly illustrating an electronic system according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these example embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted. Well-known structures and well-known technologies may not be specifically described in order to avoid ambiguous interpretation of the present invention.

It will be understood that when an element or layer is referred to as being “connected to” or “coupled to” another element or layer, it can be directly connected or coupled to the other element or layer or intervening elements or layers may be present. In contrast, when an element is referred to as being “directly connected to” or “directly coupled to” another element or layer, there are no intervening elements or layers present. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of example embodiments of the inventive concepts.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated components, steps, operations, and/or elements, but do not preclude the presence or addition of one or more other components, steps, operations, elements, and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “below,” “beneath,” “lower,” “above,” “upper,” and the like, may be used herein for ease of description to describe one device or element's relationship to another device(s) or element(s) as illustrated in the drawings. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Hereinafter, example embodiments of the inventive concepts will be described with respect to a resistive random access memory (RRAM) or a ferroelectric random access memory (FRAM). Example embodiments are not limited to RRAM and FRAM technologies. It will be apparent to those of ordinary skill in the art to which example embodiments of the inventive concepts pertain that the inventive concepts may be applied to many different devices. For example, the inventive concepts may be applied to all non-volatile memory devices using resistance materials (e.g., phase-change random access memories (PRAMs) and magnetic random access memories (MRAMs)).

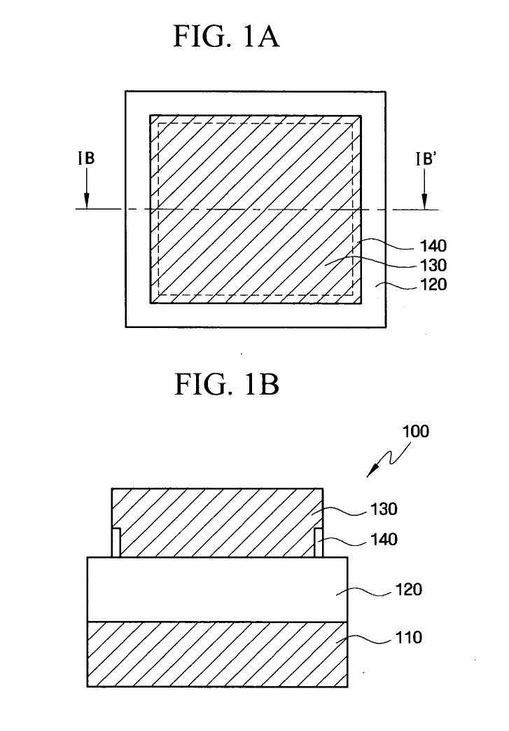

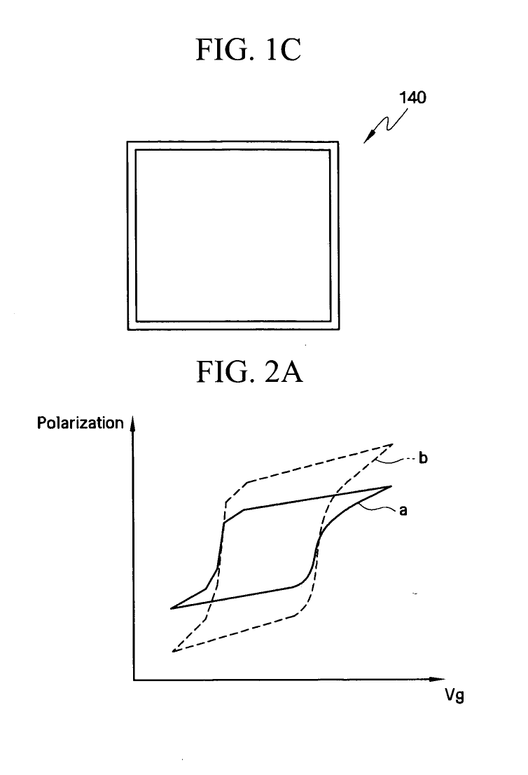

A non-volatile memory device according to example embodiments of the inventive concepts will now be described with reference to FIGS. 1A-1C. FIG. 1A is a plan view of a non-volatile memory device according to example embodiments of the inventive concepts. FIG. 1B is a cross-sectional view of the non-volatile memory device of FIG. 1A taken along the line IB-IB′. FIG. 1C is a plan view of the adhesive layer 140 of the non-volatile memory device illustrated in FIGS. 1A and 1B. Referring to FIGS. 1A-1C, a non-volatile memory device according to example embodiments may include a lower electrode 110 on a substrate (not shown), an active memory material 120 on the lower electrode 110, an upper electrode 130 on the active memory material 120, and an adhesive layer 140 in a region between the active memory material 120 and the upper electrode 130. The active memory material 120 may contact the upper electrode 130 and the adhesive layer 140.

The lower electrode 110 may include, for example, Al, Cr, Hf, HfN, Zr, ZrN, Ti, TiN, Ta, TaN, WN, Pt, Au, Ag, Ir, Ru, and/or Pd. The upper electrode 130 may include, for example, Al, Cr, Hf, HfN, Zr, ZrN, Ti, TiN, Ta, TaN, WN, Pt, Au, Ag, Ir, Ru, and/or Pd. The adhesive layer 140 may include, for example, poly(methyl methacrylate) (PMMA). The adhesive layer 140 may include a material having a lower glass transition temperature (Tg) than the active memory material 120. The adhesive layer 140 may include a material that softens the active memory material 120 without changing a phase thereof. The active memory material 120 may include, for example, a ferroelectric material or a variable resistance material.

In a case where the active memory material 120 is a ferroelectric material, the non-volatile memory device according to example embodiments of the inventive concepts may be, for example, a FRAM. In a case where the active memory material 120 is a variable resistance material, the non-volatile memory device according to example embodiments of the inventive concepts may be, for example, a RRAM. The non-volatile memory device according to example embodiments of the inventive concepts may include any resistance material, depending on the type of the active memory material 120.

The adhesive layer 140 may contact part of the active memory material 120. The adhesive layer 140 may surround the upper electrode 130 as shown in FIGS. 1A-1C. The adhesive layer 140 may be ring-shaped and the upper electrode 130 may fill the inside of the adhesive layer 140. The adhesive layer 140 may be thinner than the upper electrode 130. The upper electrode 130 may be thicker than the adhesive layer 140 and may extend over the adhesive layer 140 (e.g., overlap the adhesive layer 140). The upper electrode 130 may cover the adhesive layer 140.

In a non-volatile memory device according to example embodiments of the inventive concepts, the adhesive layer 140 may be formed in only part of a region extending between the upper electrode 130 and the active memory material 120. The adhesive layer 140 may be between less than all of the nearest surfaces of the upper electrode 130 and the active memory material 120. The adhesive layer may partially separate the upper electrode 130 from the active memory material 120. In a case where the adhesive layer 140 is not included between the upper electrode 130 and the active memory material 120, the adhesive strength between the upper electrode 130 and the active memory material 120 may be reduced. In a case where the adhesive layer 140 fills a region between the upper electrode 130 and the active memory material 120 (e.g., the adhesive layer 140 completely separates the upper electrode 130 and the active material 120), characteristics of the non-volatile memory device may deteriorate.

In the non-volatile memory device according to example embodiments of the inventive concepts, the adhesive layer 140 may be formed in only part of a region between the upper electrode 130 and the active memory material 120 in order to enhance the adhesive strength between the upper electrode 130 and the active memory material 120 while preventing and/or reducing deterioration of characteristics of the non-volatile memory device due to the adhesive layer 140.

A non-volatile memory device according to example embodiments of the inventive concepts including a ferroelectric material (e.g., an FRAM) will now be described in more detail.

When a membranous material is added to an interface between an active memory material and an electrode, a depolarization electric (E)-field may exist. The depolarization E-field may be an electric field that suppresses polarization of an FRAM. As the depolarization E-field decreases, a non-volatile memory device may exhibit improved characteristics. The polarization E-field may be described by Equation 1.

E=P*Cf/∈(Cis+Cf). Equation 1

Referring to Equation 1, E may indicate a depolarization E-field, P may indicate a depolarization constant, Cf may indicate capacitance of an FRAM, and Cis may indicate capacitance of a material added to an interface between an FRAM (active memory material) and an electrode. Cis may equal ∈A/d. A may be an area of an interface between the upper electrode 130 and the active memory material 120. d may be a distance between the upper electrode 130 and the active memory material 120. ∈ may be the dielectric constant of a material separating the upper electrode 130 and the active memory material 120.

The capacitance Cis may contribute to characteristics of a non-volatile memory device. An increase in the capacitance Cis may result in a reduction of the depolarization E-field. Because Cis=∈A/d, “d” may be reduced or “A” may be increased in order to increase the capacitance Cis. In the non-volatile memory device according to example embodiments of the inventive concepts, “d” may reduced and the capacitance Cis may increase. In an FRAM, the sum of the capacitance Cis of a region where an adhesive layer is formed and the capacitance Cis of a region where the adhesive layer is not formed may be relatively large due to the capacitive contribution of the region where the adhesive layer is not formed. The depolarization E-field may be reduced. This reduction in the depolarization E-field that may interfere with polarization may increase polarization. Characteristics of the non-volatile memory device may be enhanced.

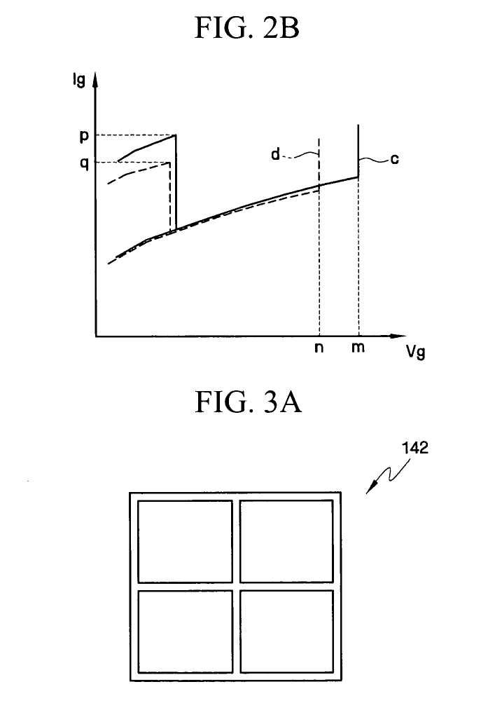

FIG. 2A is a graph of polarization as a function of gate voltage (Vg) illustrating variation in characteristics of the non-volatile memory device according to example embodiments of the inventive concepts when a non-volatile memory device is an FRAM. In the graph of FIG. 2A, “a” represents the variation in characteristics of an FRAM in a case where the adhesive layer 140 is in an entire region between the upper electrode 130 and an active memory element (e.g., completely separates the upper electrode 130 and an active memory element), and “b” represents the variation in characteristics of an FRAM when the adhesive layer 140 is in only part of a region between the upper electrode 130 and the active memory element (e.g., partially separates the upper electrode 130 and an active memory element). The x-axis represents a gate voltage and the y-axis represents polarization. Referring to FIG. 2A, “b” has a greater polarization than “a,” which may indicate improvement in the characteristics of the FRAM.

FIG. 2B is a graph of gate current (Ig) as a function of gate voltage (Vg) illustrating variation in characteristics of the non-volatile memory device according to example embodiments of the inventive concepts when the non-volatile memory device is an RRAM. In the graph of FIG. 2B, “c” represents the variation in characteristics of an RRAM in a case where the adhesive layer 140 is in an entire region between the upper electrode 130 and an active memory element (e.g., completely separates the upper electrode 130 and the active memory element), and “d” represents the variation in characteristics of an RRAM when the adhesive layer 140 is in only part of a region between the upper electrode 130 and the active memory element (e.g., partially separates the upper electrode 130 and an active memory element). The x-axis represents a gate voltage and the y-axis represents a gate current. Referring to FIG. 2B, a set gate voltage “m” of “c” is higher than a set gate voltage “n” of “d,” and a reset gate current “p” of “c” is greater than a reset gate current “q” of “d.” More power may be required in the case of the RRAM “c” than the RRAM “d”. Characteristics of the RRAM “d” may be enhanced relative to the RRAM “c”.

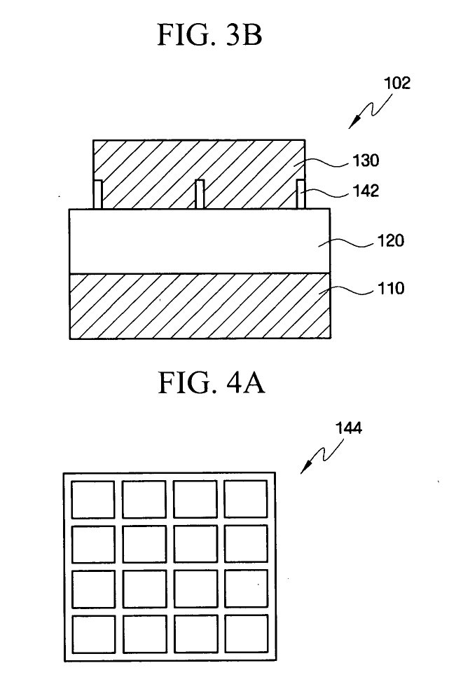

Non-volatile memory devices according to example embodiments of the inventive concepts will now be described with reference to FIGS. 3A-5B. FIGS. 3A-5B are diagrams illustrating example embodiments of the inventive concepts. FIGS. 3A, 4A, and 5A are diagrams respectively showing adhesive layers 142, 144, and 146, according to example embodiments of the inventive concepts. FIGS. 3B, 4B, and 5B, are cross-sectional diagrams of non-volatile memory devices 102, 104, and 106, respectively, according to example embodiments of the inventive concepts.

Referring to FIGS. 3A and 3B, the non-volatile memory device 102 according to example embodiments of the inventive concepts may include an adhesive layer 142 in a lattice pattern. The adhesive layer 142 may surround an upper electrode 130 and the lattice pattern may divide the adhesive layer 142 to include one or more regions. The regions of the adhesive layer 142 may be filled with the upper electrode 130.

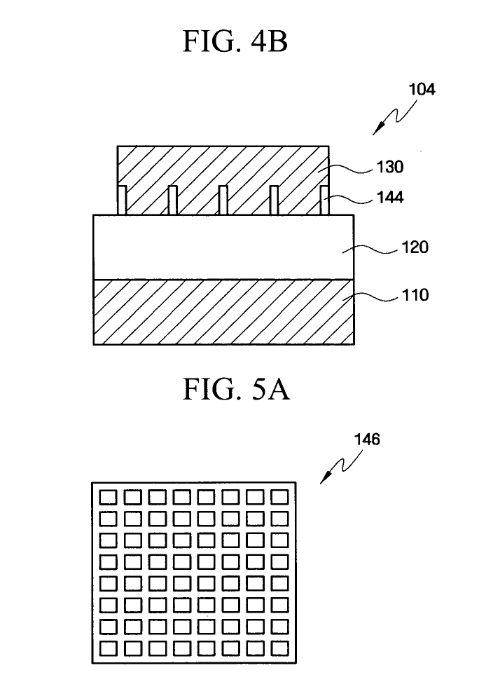

Referring to FIGS. 4A and 4B, the non-volatile memory device 104 according to example embodiments of the inventive concepts may include an adhesive layer 144 in a lattice pattern. The adhesive layer 144 may surround an upper electrode 130 and the lattice pattern may divide the adhesive layer 144 to include 16 regions. The 16 regions of the adhesive layer 144 may be filled with the upper electrode 130.

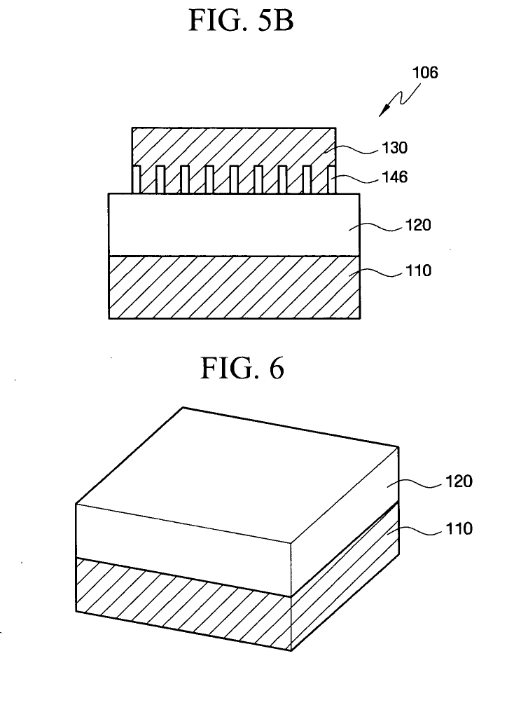

Referring to FIGS. 5A and 5B, the non-volatile memory device 106 according to example embodiments of the inventive concepts may include an adhesive layer 146 in a lattice pattern. The adhesive layer 146 may surround an upper electrode 130 and the lattice pattern may divide the adhesive layer 146 to include a large number of regions. The regions of the adhesive layer 146 may be filled with the upper electrode 130.

In each non-volatile memory device 102, 104, or 106 according to example embodiments of the inventive concepts, the adhesive strength between an upper electrode 130 and an active memory material 120 may be increased by the adhesive layer 142, 144, or 146. Because the adhesive layer 142, 144, or 146 may not be on the entire surface of the active memory material 120 and may be on part of the surface of the active memory material 120, characteristics of the non-volatile memory device 102, 104, or 106 may be enhanced.

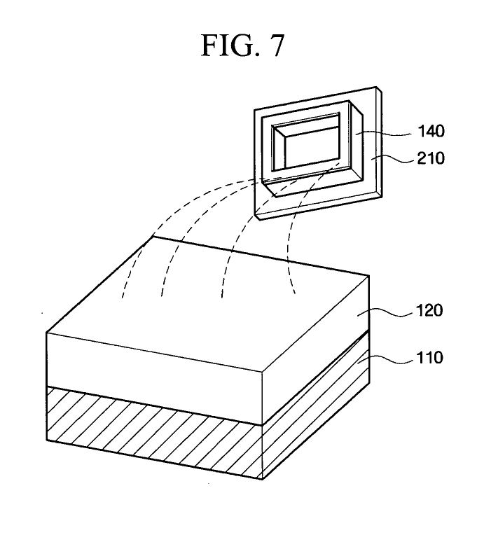

Hereinafter, methods of fabricating non-volatile memory devices according to example embodiments of the inventive concepts will be described with reference to FIGS. 6-9. FIGS. 6-9 are diagrams illustrating methods of fabricating a non-volatile memory device according to example embodiments of the inventive concepts. Referring to FIG. 6, a lower electrode 110 and an active memory material 120 may be sequentially deposited. Referring to FIG. 7, an adhesive layer 140 may be deposited (e.g., printed) on the active memory material 120. A printing method may include, for example, inkjet printing, intaglio printing, screen printing, flexographic printing, offset printing, stamp printing, gravure printing, and/or a heat- and laser-induced process.

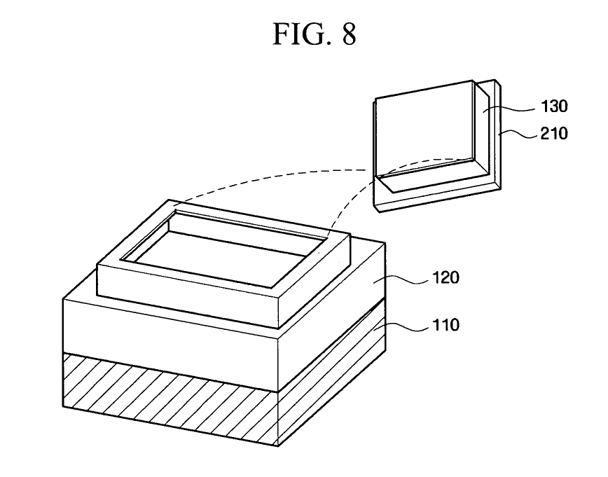

The adhesive layer 140 may be adhered to a printing mold 210 and then printed accordingly on the active memory material 120. The adhesive layer 140 may be, for example, ring-shaped as shown in FIG. 7 and/or may be shaped as shown in FIG. 3A, 4A, or 5A. One having ordinary skill in the art will understand that the particular shape or configuration (e.g., lattice configuration) are not limited by example embodiments of the inventive concepts and may be a wide variety of different shapes and configurations. For example, the adhesive layer 140 may be a partial circular lattice. Referring to FIG. 8, an upper electrode 130 may be printed on the active memory material 120 having the adhesive layer 140. The upper electrode 130 may be formed to fill regions on the active memory material 120 where the adhesive layer 140 is not formed. The adhesive layer 140 may be formed to surround the upper electrode 130. The upper electrode 130 may be taller (e.g., thicker) than the adhesive layer 140 and may extend upward from the adhesive layer 140. The upper electrode 130 may fill the inside of the adhesive layer 140 and may extend upward and over the adhesive layer 140.

The upper electrode 130 may be formed as a metal layer. When the upper electrode 130 is a metal layer liquefied for printing, partial spreading of the upper electrode 130 may occur in a printing process. In the non-volatile memory device 100 according to example embodiments of the inventive concepts, the adhesive layer 140 surrounding the upper electrode 130 may function as a barrier layer. Because the adhesive layer 140 surrounds the upper electrode 130, spreading of the upper electrode 130 may be reduced and/or prevented.

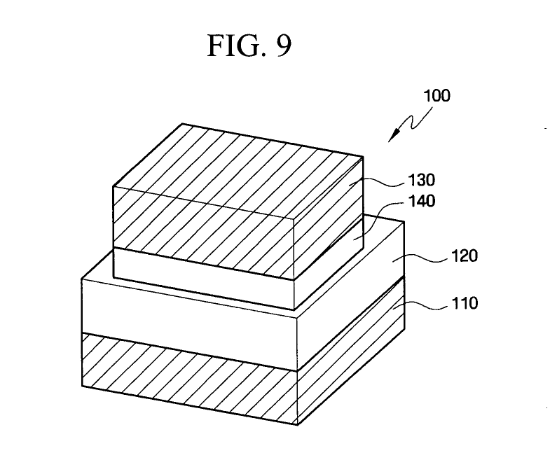

Referring to FIG. 9, the non-volatile memory device 100 according to example embodiments of the inventive concepts may include the lower electrode 110 formed on a substrate (not shown), the active memory material 120 formed on the lower electrode 110, the upper electrode 130 formed on the active memory material 120, and the adhesive layer 140 formed in part of a region between the active memory material 120 and the upper electrode 130. The active memory material 120 may contact the upper electrode 130 and the adhesive layer 140.

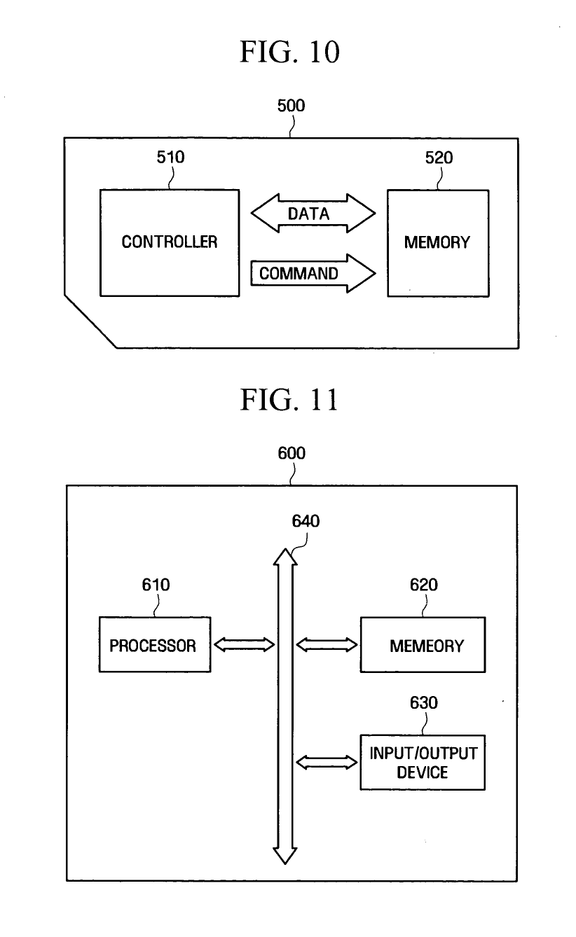

FIG. 10 is a schematic diagram illustrating a memory card 500 according to example embodiments of the inventive concepts. Referring to FIG. 10, a controller 510 and a memory 520 may exchange electric signals. For example, according to commands of the controller 510, the memory 520 and the controller 510 may exchange data. Accordingly, the memory card 500 may either store data in the memory 520 or output data from the memory 520. The memory 520 may include one of the non-volatile memory devices described above in reference to FIGS. 1-9.

The memory card 500 may be used as a storage medium for various portable electronic devices. For example, the memory card 500 may be a multimedia card (MMC) or a secure digital (SD) card.

FIG. 11 is a block diagram roughly illustrating an electronic system 600 according to example embodiments of the inventive concepts. Referring to FIG. 11, a processor 610, an input/output device 630, and a memory 620 may perform data communication with each other by using a bus 640. The processor 610 may execute a program and control the electronic system 600. The input/output device 630 may be used to input/output data to/from the electronic system 600. The electronic system 600 may be connected to an external device (e.g. a personal computer and/or a network) by using the input/output device 630 and may exchange data with the external device.

The memory 620 may store codes or programs for operations of the processor 610. For example, the memory 620 may include one of the non-volatile memory devices described above in reference to FIGS. 1-9.

For example, such an electronic system 600 may embody various electronic control systems requiring the memory 620, and, for example, may be used in mobile phones, MP3 players, navigation devices, solid state disks (SSD), household appliances and the like.

While example embodiments of the inventive concepts have been particularly shown and described with reference to exemplary embodiments thereof, it will be understood by those of ordinary skill in the art that various changes in form and detail may be made therein without departing from the spirit and scope of the claims. The example embodiments of the inventive concepts should be considered in a descriptive sense only and not for purposes of limitation.

1. A non-volatile memory device, comprising:
an active memory layer;
an electrode on the active memory layer; and
an adhesive layer between part of the active memory layer and part of the electrode.

2. The non-volatile memory device of claim 1, wherein the active memory layer includes an active memory material that is one of a ferroelectric material and a variable resistance material.

3. The non-volatile memory device of claim 1, wherein the active memory layer contacts the electrode and the adhesive layer.

4. The non-volatile memory device of claim 1, wherein the adhesive layer surrounds one or more regions of the electrode.

5. The non-volatile memory device of claim 1, wherein the adhesive layer is in a lattice pattern.

6. The non-volatile memory device of claim 4, wherein the one or more regions of the electrode fill one or more spaces between one or more regions of the adhesive layer.

7. The non-volatile memory device of claim 5, wherein the electrode fills spaces in the lattice pattern.

8. The non-volatile memory device of claim 6, wherein the adhesive layer is thinner than the electrode, and
the electrode extends beyond the adhesive layer.

9. The non-volatile memory device of claim 8, wherein the electrode overlaps the adhesive layer.

10. The non-volatile memory device of claim 1, further comprising a second electrode on the active memory layer, the second electrode separated from the electrode.

11. The non-volatile memory device of claim 1, wherein the electrode includes at least one of Al, Cr, Hf, HfN, Zr, ZrN, Ti, TiN, Ta, TaN, WN, Pt, Au, Ag, Ir, Ru, and Pd.

12. The non-volatile memory device of claim 10, wherein the second electrode includes at least one of Al, Cr, Hf, HfN, Zr, ZrN, Ti, TiN, Ta, TaN, WN, Pt, Au, Ag, Ir, Ru, and Pd.

13. The non-volatile memory device of claim 1, wherein the adhesive layer includes an adhesive material configured to soften the active memory layer, and
the adhesive layer has a lower glass transition temperature than the active memory layer.

14. The non-volatile memory device of claim 13, wherein the adhesive material is poly(methyl methacrylate).

15.-18. (canceled)

19. A memory card comprising the non-volatile memory device of claim 1.

20. An electronic system comprising the non-volatile memory device of claim 1.
